(19) United States
(12) Patent Application Publication
(10) Pub. No.: US 2025/0287693 A1
(43) Pub. Date: Sep. 11, 2025

(54) ACTIVE MATRIX SUBSTRATE, DISPLAY DEVICE AND METHOD FOR MANUFACTURING ACTIVE MATRIX SUBSTRATE

(71) Applicant: Sharp Display Technology Corporation, Kameyama City (JP)

(72) Inventors: Tatsuya KAWASAKI, Kameyama City (JP); Tohru DAITOH, Kameyama City (JP); Hajime IMAI, Kameyama City (JP); Teruyuki UEDA, Kameyama City (JP); Kengo HARA, Kameyama City (JP)

(21) Appl. No.: 19/062,322

(22) Filed: Feb. 25, 2025

(30) Foreign Application Priority Data
Mar. 11, 2024 (JP) 2024-037384

(51) Int. Cl. H10D 86/40; H10H 29/01

(52) U.S. Cl. CPC H10D 86/441; H10D 86/423; H10H 29/012

(57) ABSTRACT

A pixel TFT is an oxide semiconductor TFT having a top gate structure. The active matrix substrate includes a first interlayer insulating layer covering the gate electrode and the oxide semiconductor layer and a second interlayer insulating layer provided on the first interlayer insulating layer, and the source electrode is provided on the second interlayer insulating layer. The first interlayer insulating layer includes a first source opening. The second interlayer insulating layer includes a second source opening located inside the first source opening. The source electrode is electrically connected to a source contact region of the oxide semiconductor layer in the second source opening.

### CROSS-REFERENCE TO RELATED APPLICATIONS

This application claims the benefit of priority to Japanese Patent Application Number 2024-037384 filed on Mar. 11, 2024. The entire contents of the above-identified application are hereby incorporated by reference.

### BACKGROUND

### Technical Field

The disclosure relates to an active matrix substrate and a display device. The disclosure also relates to a method of manufacturing an active matrix substrate.

Currently, a display device that is widely used includes an active matrix substrate provided with switching elements on a pixel-by-pixel basis. An active matrix substrate provided with thin film transistors (hereinafter referred to as a “TFT”) as the switching elements is referred to as a TFT substrate. Note that, in the present specification, a region of the TFT substrate corresponding to a pixel of the display device is referred to as a pixel region. The TFT provided as a switching element to each pixel region of the active matrix substrate may be referred to as a “pixel TFT”.

In recent years, there is proposed use of an oxide semiconductor as a material of an active layer of the TFT, in place of amorphous silicon and polycrystalline silicon. A TFT having an oxide semiconductor film as an active layer is referred to as an “oxide semiconductor TFT”. JP 2012-134475 A discloses an active matrix substrate in which an In—Ga—Zn—O based semiconductor film is used in an active layer of a TFT.

The oxide semiconductor has mobility higher than that of amorphous silicon. Thus, the oxide semiconductor TFT can operate at a higher speed than an amorphous silicon TFT. In addition, since an oxide semiconductor film is formed by a process simpler than that of a polycrystalline silicon film, the oxide semiconductor film can be applied to a device that requires a large area.

A structure of the TFT is roughly classified into a bottom gate structure and a top gate structure. Currently, the bottom gate structure is often adopted for the oxide semiconductor TFT, but it is also proposed to use the top gate structure (see, for example, JP 2012-204077 A). In the top gate structure, the gate insulating layer can be thinned, resulting in high current supply performance.

### SUMMARY

In recent years, an increase in the definition of display devices has progressed. In a high-definition display device, it is necessary to reduce the pixel size while maintaining a sufficiently high aperture ratio. Thus, there is a demand for a pixel structure that can improve the aperture ratio by reducing the size of a pixel TFT, miniaturizing a wiring line, or the like.

The disclosure has been conceived in light of the above-described problem, and an object of the disclosure is to improve the aperture ratio of the active matrix substrate including the oxide semiconductor TFT having the top gate structure and the display device.

According to the embodiment of the disclosure, there is provided an active matrix substrate, a display device, and a method of manufacturing the active matrix substrate, which are described in the following items.

### Item 1

Active matrix substrate including a display region including
a plurality of pixel regions, and a peripheral region located around the display region,
a substrate,
a pixel TFT supported by the substrate and provided corresponding to each of the plurality of pixel regions, and
a pixel electrode disposed in each of the plurality of pixel regions and electrically connected to the pixel TFT, the pixel TFT including an oxide semiconductor layer including a channel region, and a source contact region and a drain contact region located on both sides of the channel region, respectively, a gate insulating layer provided on the channel region of the oxide semiconductor layer, a gate electrode provided on the gate insulating layer and facing the channel region via the gate insulating layer, and a source electrode electrically connected to the source contact region of the oxide semiconductor layer,
wherein the active matrix substrate further includes a first interlayer insulating layer covering the gate electrode and the oxide semiconductor layer and a second interlayer insulating layer provided on the first interlayer insulating layer,
the source electrode is provided on the second interlayer insulating layer,
the first interlayer insulating layer includes a first source opening formed so as to expose at least a part of the source contact region,
the second interlayer insulating layer includes a second source opening formed so as to be smaller than the first source opening and to be located inside the first source opening in a plan view, and
the source electrode is connected to the source contact region in the second source opening.

### Item 2

The active matrix substrate according to item 1,
wherein the pixel TFT includes a drain electrode electrically connected to the drain contact region of the oxide semiconductor layer,
the drain electrode is provided on the second interlayer insulating later,
the first interlayer insulating layer includes a first drain opening formed so as to expose at least a part of the drain contact region,
the second interlayer insulating layer includes a second drain opening formed so as to be smaller than the first drain opening and to be located inside the first drain opening in a plan view, and
the drain electrode is connected to the drain contact region in the second drain opening.

### Item 3

The active matrix substrate according to item 1 or 2,
wherein the peripheral region includes a first connection portion electrically connecting a first wiring line made of the same conductive film as the gate electrode to a second wiring line made of the same conductive film as the source electrode,
the first interlayer insulating layer includes a first gate opening formed so as to expose at least a part of the first wiring line,
the second interlayer insulating layer includes a second gate opening formed so as to be smaller than the first gate opening and to be located inside the first gate opening in a plan view, and
the second wiring line is connected to the first wiring line in the second gate opening.

### Item 4

The active matrix substrate according to any one of items 1 to 3, further including
a light blocking layer provided on the substrate and having electrical conductivity, and
a lower insulating layer covering the light blocking layer,
wherein the oxide semiconductor layer is provided on the lower insulating layer,
the peripheral region includes a second connection portion electrically connecting a third wiring line made of the same conductive film as the light blocking layer to a fourth wiring line made of the same conductive film as the source electrode,
the first interlayer insulating layer includes a first bottom opening formed so as to expose at least a part of the third wiring line,
the lower insulating layer includes a second bottom opening formed so as to be smaller than the first bottom opening and to be located inside the first bottom opening in a plan view,
the second interlayer insulating layer includes a third bottom opening formed so as to be smaller than the first bottom opening and to be located inside the first bottom opening in a plan view, the third bottom opening being continuous with the second bottom opening, and
the fourth wiring line is connected to the third wiring line in the second bottom opening and the third bottom opening.

### Item 5

Active matrix substrate including
a display region including a plurality of pixel regions, and a peripheral region located around the display region,
a substrate,
a pixel TFT supported by the substrate and provided corresponding to each of the plurality of pixel regions, and
a pixel electrode disposed in each of the plurality of pixel regions and electrically connected to the pixel TFT, the pixel TFT including an oxide semiconductor layer including a channel region, and a source contact region and a drain contact region located on both sides of the channel region, respectively, a gate insulating layer provided on the channel region of the oxide semiconductor layer, a gate electrode provided on the gate insulating layer and facing the channel region via the gate insulating layer, and a drain electrode electrically connected to the drain contact region of the oxide semiconductor layer,
wherein the active matrix substrate further includes a first interlayer insulating layer covering the gate electrode and the oxide semiconductor layer and a second interlayer insulating layer provided on the first interlayer insulating layer,
the drain electrode is provided on the second interlayer insulating layer,
the first interlayer insulating layer includes a first drain opening formed so as to expose at least a part of the drain contact region,
the second interlayer insulating layer includes a second drain opening formed so as to be smaller than the first drain opening and to be located inside the first drain opening in a plan view, and
the drain electrode is connected to the drain contact region in the second drain opening.

### Item 6

The active matrix substrate according to item 5,
wherein the peripheral region includes a first connection portion electrically connecting a first wiring line made of the same conductive film as the gate electrode to a second wiring line made of the same conductive film as the drain electrode,
the first interlayer insulating layer includes a first gate opening formed so as to expose at least a part of the first wiring line,
the second interlayer insulating layer includes a second gate opening formed so as to be smaller than the first gate opening and to be located inside the first gate opening in a plan view, and
the second wiring line is connected to the first wiring line in the second gate opening.

### Item 7

The active matrix substrate according to item 5 or 6, further including
a light blocking layer provided on the substrate and having electrical conductivity, and
a lower insulating layer covering the light blocking layer,
wherein the oxide semiconductor layer is provided on the lower insulating layer,
the peripheral region includes a second connection portion electrically connecting a third wiring line made of the same conductive film as the light blocking layer to a fourth wiring line made of the same conductive film as the drain electrode,
the first interlayer insulating layer includes a first bottom opening formed so as to expose at least a part of the third wiring line,
the lower insulating layer includes a second bottom opening formed so as to be smaller than the first bottom opening and to be located inside the first bottom opening in a plan view,
the second interlayer insulating layer includes a third bottom opening formed so as to be smaller than the first bottom opening and to be located inside the first bottom opening in a plan view, the third bottom opening being continuous with the second bottom opening, and
the fourth wiring line is connected to the third wiring line in the second bottom opening and the third bottom opening.

### Item 8

The active matrix substrate according to any one of items 1 to 7, wherein a thickness of the second interlayer insulating layer is smaller than a thickness of the first interlayer insulating layer.

### Item 9

The active matrix substrate according to any one of items 1 to 8, wherein a thickness of the second interlayer insulating layer is 200 nm or less.

### Item 10

The active matrix substrate according to any one of items 1 to 9, wherein the second interlayer insulating layer is a silicon nitride layer or has a layered structure including a silicon oxide layer and a silicon nitride layer formed on the silicon oxide.

### Item 11

The active matrix substrate according to any one of items 1 to 10, wherein the oxide semiconductor layer includes an In—Ga—Zn—O based semiconductor.

### Item 12

The active matrix substrate according to item 11, wherein the In—Ga—Zn—O based semiconductor includes a crystalline portion.

### Item 13

A display device including the active matrix substrate according to any one of items 1 to 12.

### Item 14

The display device according to item 13, wherein the display device is a liquid crystal display device including a counter substrate disposed facing the active matrix substrate and a liquid crystal layer provided between the active matrix substrate and the counter substrate.

### Item 15

A method of manufacturing the active matrix substrate according to item 1, including
(A) a step of forming the oxide semiconductor layer, the gate insulating layer, and the gate electrode,
(B) a step of forming the first interlayer insulating layer so as to cover the gate electrode and the oxide semiconductor layer,
(C) a step of forming the first source opening in the first interlayer insulating layer by a photolithography process and etching,
(D) a step of forming the second interlayer insulating layer on the first interlayer insulating layer and in the first source opening,
(E) a step of forming the second source opening in the second interlayer insulating layer by a photolithography process and etching, and
(F) a step of forming the source electrode on the second interlayer insulating layer and in the second source opening.

### Item 16

A method of manufacturing an active matrix substrate according to Item 5, including
(A) a step of forming the oxide semiconductor layer, the gate insulating layer, and the gate electrode,
(B) a step of forming the first interlayer insulating layer so as to cover the gate electrode and the oxide semiconductor layer,
(C) a step of forming the first drain opening in the first interlayer insulating layer by a photolithography process and etching,
(D) a step of forming the second interlayer insulating layer on the first interlayer insulating layer and in the first drain opening,
(E) a step of forming the second drain opening in the second interlayer insulating layer by a photolithography process and etching, and
(F) a step of forming the drain electrode on the second interlayer insulating layer and in the second drain opening.

According to embodiments of the disclosure, the aperture ratio of the active matrix substrate including the oxide semiconductor TFT having the top gate structure and the display device can be improved.

### BRIEF DESCRIPTION OF DRAWINGS

The disclosure will be described with reference to the accompanying drawings, wherein like numbers reference like elements.

FIG. 1 is a schematic diagram illustrating an example of a planar structure of an active matrix substrate 100 according to an embodiment of the disclosure.

FIG. 2 is a plan view schematically illustrating the active matrix substrate 100.

FIG. 3 is a cross-sectional view schematically illustrating the active matrix substrate 100, taken along a line 3A-3A′ in FIG. 2.

FIG. 4A is a process cross-sectional view illustrating a manufacturing process for the active matrix substrate 100.

FIG. 4B is a process cross-sectional view illustrating a manufacturing process for the active matrix substrate 100.

FIG. 4C is a process cross-sectional view illustrating a manufacturing process for the active matrix substrate 100.

FIG. 5A is a process cross-sectional view illustrating a manufacturing process for the active matrix substrate 100.

FIG. 5B is a process cross-sectional view illustrating a manufacturing process for the active matrix substrate 100.

FIG. 5C is a process cross-sectional view illustrating a manufacturing process for the active matrix substrate 100.

FIG. 6A is a process cross-sectional view illustrating a manufacturing process for the active matrix substrate 100.

FIG. 6B is a process cross-sectional view illustrating a manufacturing process for the active matrix substrate 100.

FIG. 6C is a process cross-sectional view illustrating a manufacturing process for the active matrix substrate 100.

FIG. 7A is a process cross-sectional view illustrating a manufacturing process for the active matrix substrate 100.

FIG. 7B is a process cross-sectional view illustrating a manufacturing process for the active matrix substrate 100.

FIG. 8A is a process cross-sectional view illustrating a manufacturing process for the active matrix substrate 100.

FIG. 8B is a process cross-sectional view illustrating a manufacturing process for the active matrix substrate 100.

FIG. 9 is a cross-sectional view schematically illustrating an active matrix substrate 900 of a comparative example.

FIG. 10 is a cross-sectional view schematically illustrating another active matrix substrate 200 according to an embodiment of the disclosure.

FIG. 11 is a cross-sectional view schematically illustrating yet another active matrix substrate 300 according to an embodiment of the disclosure.

FIG. 12 is a cross-sectional view schematically illustrating a liquid crystal display device 1000 including the active matrix substrate 100 (200, 300) according to an embodiment of the disclosure.

### DESCRIPTION OF EMBODIMENTS

Hereinafter, embodiments of the disclosure will be described with reference to the accompanying drawings. Although an active matrix substrate for a liquid crystal display device performing display in a fringe field switching (FFS) mode, which is a type of transverse electrical field mode, is exemplified below as an embodiment of the disclosure, the disclosure is not limited to the following embodiments.

### First Embodiment

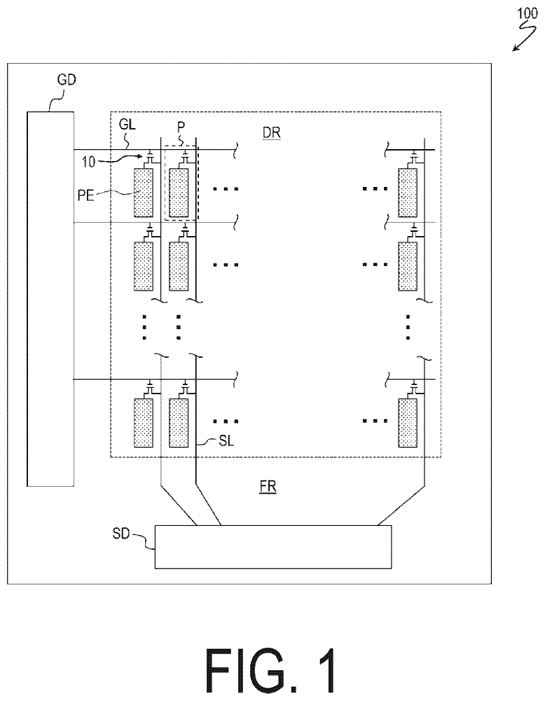

First, an active matrix substrate 100 in an embodiment will be described with reference to FIG. 1. FIG. 1 is a schematic view illustrating an example of a planar structure of the active matrix substrate 100.

The active matrix substrate 100 includes a display region DR and a peripheral region (also referred to as a “frame region” or “non-display region”) FR as illustrated in FIG. 1. The display region DR includes a plurality of pixel regions P. The plurality of pixel regions P are arrayed in a matrix shape including a plurality of rows and a plurality of columns. The pixel region P is a region corresponding to a pixel of the liquid crystal display device, and the pixel region P may be referred to as a “pixel”. The peripheral region FR is a region located in a periphery of the display region DR and does not contribute to display.

In the display region DR, a plurality of gate wiring lines GL extending in a row direction, and a plurality of source wiring lines SL extending in a column direction are formed. Each of the pixel regions P is, for example, a region surrounded by a pair of gate wiring lines GL adjacent to each other and a pair of source wiring lines SL adjacent to each other.

A peripheral circuit is provided in the non-display region FR. Here, in the non-display region FR, a gate driver GD for driving the gate wiring line GL is formed integrally (monolithically), and a source driver SD for driving the source wiring line SL is mounted. Note that in the non-display region FR, a source shared driving (SSD) circuit that drives the source bus line SL in a time division manner, or the like may be further provided and the SSD circuit or the like may be formed integrally similarly to the gate driver GD.

In each pixel region P of the display region DR, a thin film transistor (TFT) 10, and a pixel electrode PE electrically connected to the TFT 10 are disposed. The TFT 10 disposed in each pixel region P may be referred to as a “pixel TFT”. The pixel TFT 10 is supplied with a gate signal (scanning signal) from the corresponding gate wiring line GL and is supplied with a source signal (display signal) from the corresponding source wiring line SL.

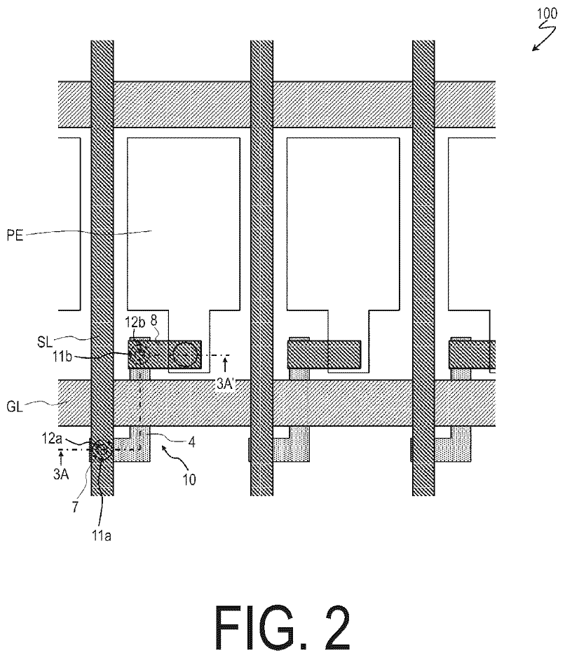

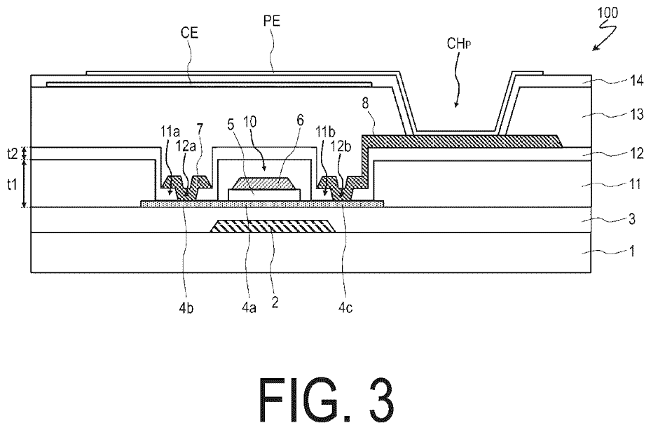

Subsequently, a more specific configuration of the active matrix substrate 100 will be described with reference to FIGS. 2 and 3. FIG. 2 is a plan view schematically illustrating the active matrix substrate 100. FIG. 3 is a cross-sectional view schematically illustrating the active matrix substrate 100, taken along a line 3A-3A′ in FIG. 2.

The active matrix substrate 100 includes a substrate 1, the pixel TFT 10 supported by the substrate 1 and provided corresponding to each pixel region P, and the pixel electrode PE disposed in each pixel region P and electrically connected to the pixel TFT 10. As described above, the active matrix substrate 100 is for a liquid crystal display device of the FFS mode, and thus the active matrix substrate 100 further includes a common electrode CE.

The substrate 1 is transparent and has insulating properties. In the illustrated example, a light blocking layer 2 having electrical conductivity is provided on the substrate 1, and a lower insulating layer 3 is provided so as to cover the light blocking layer 2. The pixel TFT 10 is provided on the lower insulating layer 3.

The pixel TFT 10 includes an oxide semiconductor layer 4, a gate insulating layer 5, a gate electrode 6, a source electrode 7, and a drain electrode 8. The pixel TFT 10 has the top gate structure.

The oxide semiconductor layer 4 is provided on the lower insulating layer 3. The oxide semiconductor layer 4 includes a channel region 4a, a source contact region 4b, and a drain contact region 4c. When viewed in a normal direction of the substrate 1 (that is, in a plan view), the channel region 4a overlaps the light blocking layer 2. Each of the source contact region 4b and the drain contact region 4c is located on both sides of the channel region 4a, respectively.

The gate insulating layer 5 is disposed on the channel region 4a of the oxide semiconductor layer 4. The gate electrode 6 is provided on the gate insulating layer 5. The gate electrode 6 faces the channel region 4a via the gate insulating layer 5. The gate electrode 6 is electrically connected to the corresponding gate bus line GL. In the illustrated example, the gate electrode 6 is formed integrally with the gate bus line GL. To be more specific, a portion of the gate bus line GL overlapping the oxide semiconductor layer 4 in a plan view functions as the gate electrode 6.

A first interlayer insulating layer 11 is provided so as to cover the gate electrode 6 and the oxide semiconductor layer 4. A second interlayer insulating layer 12 is provided on the first interlayer insulating layer 11.

The first interlayer insulating layer 11 includes a first source opening 11a and a first drain opening 11b. The first source opening 11a is formed so as to expose at least a part of the source contact region 4b. The first drain opening 11b is formed so as to expose at least a part of the drain contact region 4c. A shape of each of the first source opening 11a and the first drain opening 11b in a plan view is a substantially circular shape in the illustrated example, but is not limited thereto, and may be various shapes such as a substantially elliptical shape, a substantially rectangular shape, and a substantially regular polygonal shape.

The second interlayer insulating layer 12 includes a second source opening 12a and a second drain opening 12b. The second source opening 12a is formed so as to be smaller than the first source opening 11a and to be located inside the first source opening 11a, in a plan view. The second drain opening 12b is formed so as to be smaller than the first drain opening 11b and to be located inside the first drain opening 11b, in a plan view. A shape of each of the second source opening 12a and the second drain opening 12b in a plan view is a substantially circular shape in the illustrated example, but is not limited thereto, and may be various shapes such as a substantially elliptical shape, a substantially rectangular shape, and a substantially regular polygonal shape.

The source electrode 7 and the drain electrode 8 are provided on the second interlayer insulating layer 12. The source electrode 7 is electrically connected to the corresponding source bus line SL. In the illustrated example, the source electrode 7 is integrally formed with the source bus line SL. To be more specific, a portion of the source bus line SL overlapping the oxide semiconductor layer 4 in a plan view functions as the source electrode 7. The source electrode 7 is electrically connected to the source contact region 4b of the oxide semiconductor layer 4. As illustrated in FIG. 3, the source electrode 7 is connected to the source contact region 4b in the second source opening 12a. That is, the second source opening 12a functions as a source contact hole.

A drain electrode 8 is electrically connected to the pixel electrode PE. The drain electrode 8 is electrically connected to the drain contact region 4c of the oxide semiconductor layer 4. As illustrated in FIG. 3, the drain electrode 8 is connected to the drain contact region 4c in the second drain opening 12b. That is, the second drain opening 12b functions as a drain contact hole.

A third interlayer insulating layer 13 is provided so as to cover the pixel TFT 10. The third interlayer insulating layer 13 may be an organic insulating layer made of an organic insulating material, for example. The third interlayer insulating layer 13 may have a layered structure including an inorganic insulating layer made of an inorganic insulating material and an organic insulating layer formed on the inorganic insulating layer.

The common electrode CE is provided on the third interlayer insulating layer 13. A dielectric layer 14 is provided so as to cover the common electrode CE.

The pixel electrode PE is provided on the dielectric layer 14. The pixel electrode PE is connected to the drain electrode 8 of the pixel TFT 10 in a pixel contact hole CHₚ formed in the dielectric layer 14 and the third interlayer insulating layer 13. Although not illustrated here, the pixel electrode PE includes at least one slit (opening).

The active matrix substrate 100 is used for the liquid crystal display device of the FFS mode. The FFS mode is a display mode of a transverse electrical field method in which a pair of electrodes is provided in one of substrates, and an electrical field is applied to liquid crystal molecules in a direction (lateral direction) parallel to a substrate plane. In this example, an electrical field represented by an electric line of force is generated which extends from the pixel electrode PE, passes through a liquid crystal layer (not illustrated), and further passes through the opening having a shape of a slit of the pixel electrode PE to reach the common electrode CE. This electrical field has a component in a lateral direction with respect to the liquid crystal layer. In the transverse electrical field method, since no liquid crystal molecule rises up from the substrate, there is an advantage of achieving a wider viewing angle than a viewing angle in a vertical electrical field method.

The electrode structure in which the pixel electrode PE is disposed on the common electrode CE via the dielectric layer 14 is disclosed in WO 2012/086513, for example. Note that the common electrode CE may be disposed on the pixel electrode PE via the dielectric layer 14. Such an electrode structure is described in, for example, JP 2008-032899 A and JP 2010-008758 A. The entire contents of the disclosure of WO 2012/086513, JP 2008-032899 A, and JP 2010-008758 A are incorporated herein as reference.

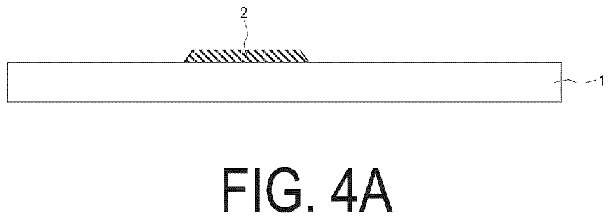

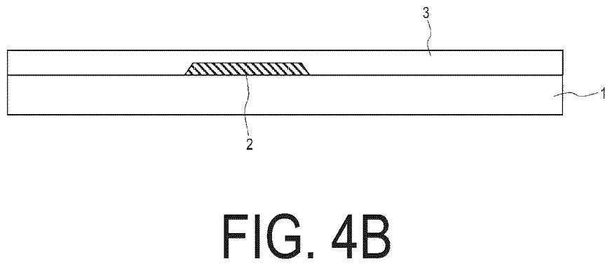

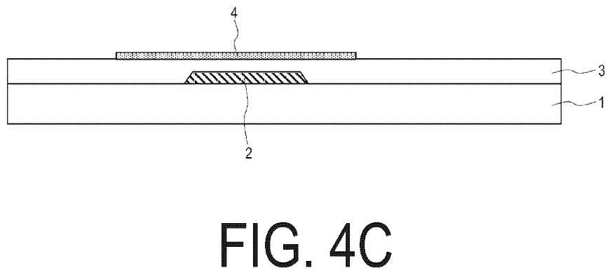

First, a method of manufacturing the active matrix substrate 100 in the embodiment will be described with reference to FIGS. 4A to 8B. FIG. 4A to FIG. 8B are process cross-sectional views for explaining the method of manufacturing the active matrix substrate 100.

First, as illustrated in FIG. 4A, the light blocking layer 2 is formed on the substrate 1. Specifically, the light blocking layer 2 can be formed by forming a conductive film (having a thickness of, for example, 50 nm or more and 500 nm or less) for the light blocking layer on the substrate 1 having insulating properties by a sputtering method or the like, and then patterning the conductive film.

A glass substrate, a plastic substrate (resin substrate) having heat resistance, or the like can be used as the substrate 1, for example.

As the conductive film for the light blocking layer, for example, a metal film including an element selected from aluminum (Al), chromium (Cr), copper (Cu), tantalum (Ta), titanium (Ti), molybdenum (Mo), or tungsten (W), or an alloy film including these elements as components can be used. A layered film including a plurality of these films may be used. For example, a layered film having a triple-layer structure of titanium film-aluminum film-titanium film, or a triple-layer structure of molybdenum film-aluminum film-molybdenum film can be used. Note that the conductive film for the light blocking layer is not limited to the triple-layer structure, and may have a single-layer, a dual-layer structure, or a layered structure of four or more layers. Here, a layered film including a lower layer of a Ti film (having a thickness from 15 nm to 70 nm) and an upper layer of a Cu film (having a thickness from 200 nm to 400 nm) is used as the conductive film for the light blocking layer.

Next, as illustrated in FIG. 4B, the lower insulating layer 3 (having a thickness of, for example, 200 nm or more and 500 nm or less) is formed so as to cover the light blocking layer 2.

Examples of the lower insulating layer 3 appropriately include a silicon oxide (SiO₂) layer, a silicon nitride (SiNx) layer, a silicon oxynitride (SiOxNy; x>y) layer, a silicon nitride oxide (SiNxOy; x>y) layer, an aluminum oxide layer, or a tantalum oxide layer. The lower insulating layer 3 may have a layered structure. Here, for example, the lower insulating layer 3 having a structure forming a layered film including a lower layer of a silicon nitride layer (having a thickness from 100 nm to 500 nm) and an upper layer of a silicon oxide layer (having a thickness from 20 nm to 300 nm) is formed by CVD.

Subsequently, as illustrated in FIG. 4C, the oxide semiconductor layer 4 is formed on the lower insulating layer 3. For example, the oxide semiconductor layer 4 can be obtained by forming an oxide semiconductor film (having a thickness, for example, from 15 nm to 200 nm) by a sputtering method and then patterning the oxide semiconductor film by a photolithography process. The oxide semiconductor film is not particularly limited and is, for example, an In—Ga—Zn—O based semiconductor film.

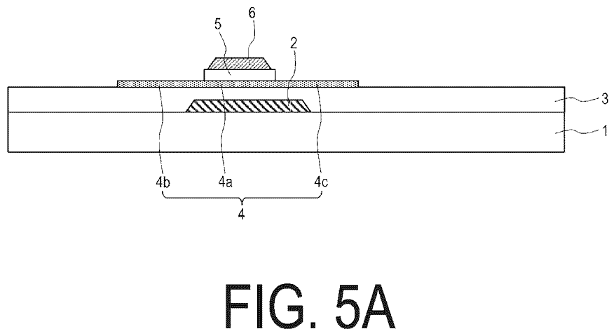

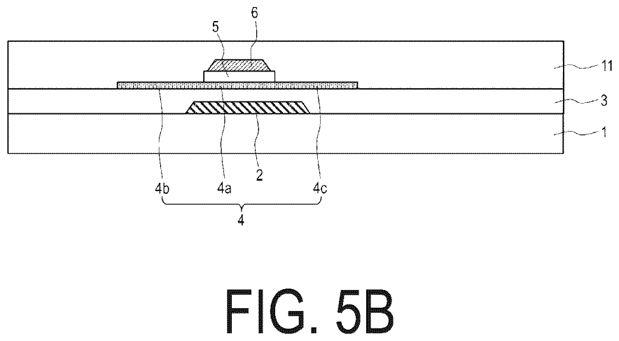

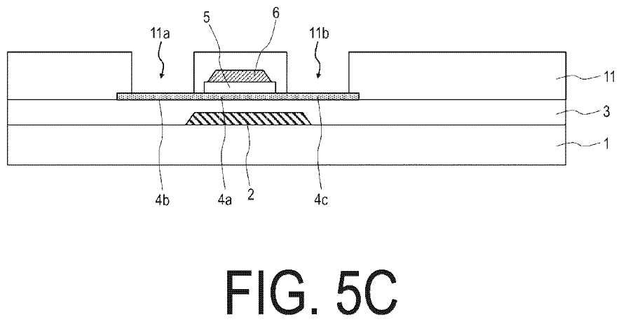

Thereafter, as illustrated in FIG. 5A, the gate insulating layer 5 and the gate electrode 6 are formed on the oxide semiconductor layer 4. Specifically, first, an insulating film (having a thickness, for example, from 80 nm to 250 nm) and a gate conductive film (having a thickness, for example, from 50 nm to 500 nm) are formed in this order so as to cover the oxide semiconductor layer 4. The insulating film can be formed using, for example, CVD, and the gate conductive film can be formed using, for example, a sputtering method. As the insulating film, an insulating film similar to the lower insulating layer 3 (insulating film exemplified as the lower insulating layer 3) can be used. A conductive film similar to the conductive film for the light blocking layer can be used as the gate conductive film. Here, for example, a silicon oxide film is used as the insulating film, and a layered film including a lower layer of a Ti film (having a thickness from 15 nm to 70 nm) and an upper layer of a Cu film (having a thickness from 200 nm to 400 nm) is used as the gate conductive film. Subsequently, the gate electrode 6 is formed by patterning the gate conductive film, and the gate insulating layer 5 is formed by patterning the insulating film. The gate conductive film can be patterned, for example, by wet etching or dry etching. The insulating film can be patterned, for example, by dry etching.

Thereafter, resistance reduction processing for the oxide semiconductor layer 4 is performed using the gate electrode 6 as a mask. The resistance reduction processing is, for example, plasma processing. As a result, regions of the oxide semiconductor layer 4 not overlapping the gate electrode 6 and the gate insulating layer 5 are low resistance regions (the source contact region 4b and the drain contact region 4c) having a lower specific resistance than a region (the channel region 4a) overlapping the gate electrode 6 and the gate insulating layer 5.

Subsequently, as illustrated in FIG. 5B, the first interlayer insulating layer 11 is formed so as to cover the gate electrode 6 and the oxide semiconductor layer 4. The first interlayer insulating layer 11 can be formed, for example, by CVD. The thickness of the first interlayer insulating layer 11 is, for example, from 300 nm to 800 nm. As the first interlayer insulating layer 11, for example, a silicon oxide layer, a silicon nitride layer, a silicon oxynitride layer, or a silicon nitride oxide layer can be used.

Subsequently, as illustrated in FIG. 5C, in the first interlayer insulating layer 11, the first source opening 11a and the first drain opening 11b are formed such that at least a part of the source contact region 4b and at least a part of the drain contact region 4c of the oxide semiconductor layer 4 are exposed. Specifically, the formation of the first source opening 11a and the first drain opening 11b can be performed by a photolithography process and etching. The etching may be dry etching, for example. The photoresist layer formed by the photolithography process is peeled after etching.

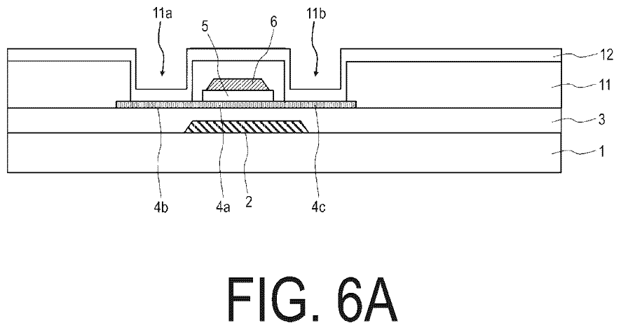

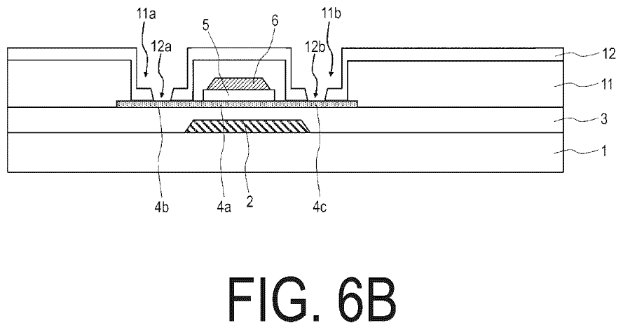

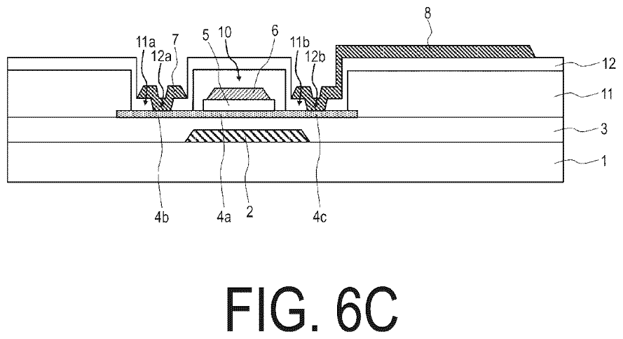

Subsequently, as illustrated in FIG. 6A, the second interlayer insulating layer 12 is formed on the first interlayer insulating layer 11, in the first source opening 11a, and in the first drain opening 11b. The second interlayer insulating layer 12 can be formed, for example, by CVD. The thickness of the second interlayer insulating layer 12 is, for example, from 50 nm to 200 nm. As the second interlayer insulating layer 12, for example, a silicon oxide layer, a silicon nitride layer, a silicon oxynitride layer, or a silicon nitride oxide layer can be used. The second interlayer insulating layer 12 may have a layered structure.

Subsequently, as illustrated in FIG. 6B, the second source opening 12a and the second drain opening 12b are formed in the second interlayer insulating layer 12. The second source opening 12a is formed so as to be smaller than the first source opening 11a and to be located inside the first source opening 11a, in a plan view. The second drain opening 12b is formed so as to be smaller than the first drain opening 11b and to be located inside the first drain opening 11b, in a plan view. Specifically, the formation of the second source opening 12a and the second drain opening 12b can be performed by a photolithography process and etching. The etching may be dry etching, for example. The photoresist layer formed by the photolithography process is peeled after etching.

Subsequently, as illustrated in FIG. 6C, the source electrode 7 is formed on the second interlayer insulating layer 12 and in the second source opening 12a, and the drain electrode 8 is formed on the second interlayer insulating layer 12 and in the second drain opening 12b. Specifically, the source electrode 7 and the drain electrode 8 can be formed by forming a source conductive film (having a thickness, for example, from 50 nm to 500 nm) on the second interlayer insulating layer 12, in the second source opening 12a, and in the second drain opening 12b, and then patterning the source conductive film. The patterning of the source conductive film can be performed, for example, by dry etching or wet etching. As the source conductive film, an element selected from aluminum (Al), chromium (Cr), copper (Cu), tantalum (Ta), titanium (Ti), molybdenum (Mo), and tungsten (W), or an alloy including these elements as components can be used, for example. For example, the source conductive film may have a triple-layer structure of titanium film-aluminum film-titanium film, or a triple-layer structure of molybdenum film-aluminum film-molybdenum film. Note that the source conductive film is not limited to the triple-layer structure, and may have a single-layer structure or a dual-layer structure, or a layered structure of four or more layers. Here, a layered film including a lower layer of a Ti film (having a thickness from 15 nm to 70 nm) and an upper layer of a Cu film (having a thickness from 200 nm to 400 nm) is used.

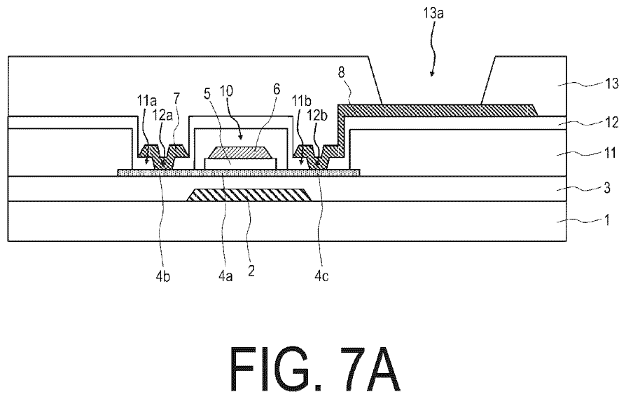

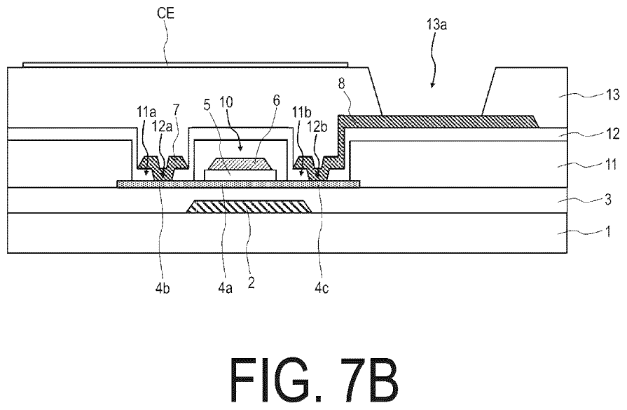

Subsequently, as illustrated in FIG. 7A, the third interlayer insulating layer 13 is formed so as to cover the pixel TFT 10. Here, as the third interlayer insulating layer 13, an organic insulating layer (having a thickness, for example, from 1 μm to 3 μm, preferably from 2 μm to 3 μm) is formed using a photosensitive resin material. An opening 13a overlapping at least a part of the drain electrode 8 is formed in the third interlayer insulating layer 13.

Subsequently, as illustrated in FIG. 7B, the common electrode CE is formed on the third interlayer insulating layer 13. Specifically, the common electrode CE can be formed by forming a transparent conductive film (having a thickness, for example, from 20 nm to 300 nm) on the third interlayer insulating layer 13, and then patterning the transparent conductive film. Here, for example, an indium-zinc oxide film is formed as the transparent conductive film by a sputtering method, and then the transparent conductive film is patterned by wet etching. Examples of a material of the transparent conductive film may include metal oxide such as ITO (indium-tin oxide), indium-zinc oxide, or ZnO.

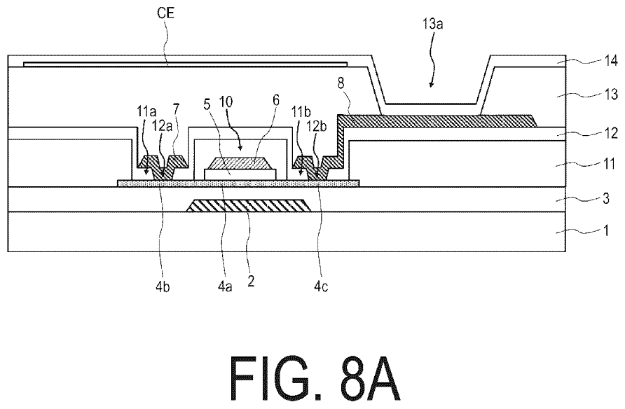

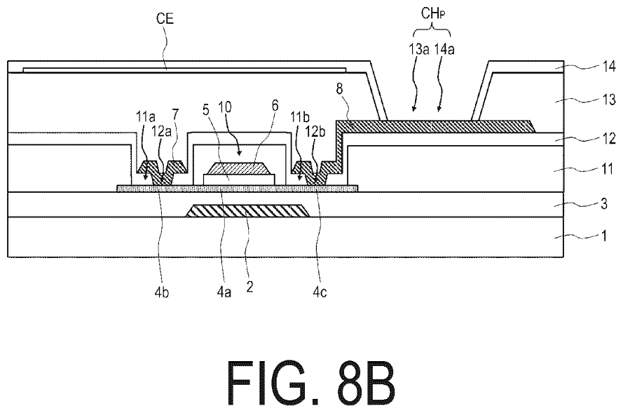

Subsequently, as illustrated in FIG. 8A, the dielectric layer 14 (having a thickness, for example, from 50 nm to 500 nm) is formed on the third interlayer insulating layer 13 and the common electrode CE. A material of the dielectric layer 14 may be the same as the material exemplified as the material of the first interlayer insulating layer 11. Here, as the dielectric layer 14, for example, a silicon nitride film is formed by CVD.

Subsequently, as illustrated in FIG. 8B, the opening 14a overlapping at least a part of the drain electrode 8 is formed in the dielectric layer 14. The formation of the opening 14a can be performed, for example, by dry etching. Thus, the pixel contact hole CH_{P} exposing at least a part of the drain electrode 8 is obtained.

Thereafter, the pixel electrode PE (having a thickness. for example, from 20 nm to 300 nm) is formed on the dielectric layer 14, so that the active matrix substrate 100 illustrated in FIG. 3 and the like can be obtained. Specifically, the formation of the pixel electrode PE can be performed by forming the transparent conductive film on the dielectric layer 14 and then patterning the transparent conductive film. A material of the transparent conductive film for the pixel electrode PE may be the same as the material exemplified as the material of the transparent conductive film for the common electrode CE. Here, an indium-zinc oxide film is formed as the transparent conductive film by a sputtering method, and then the transparent conductive film is patterned by wet etching.

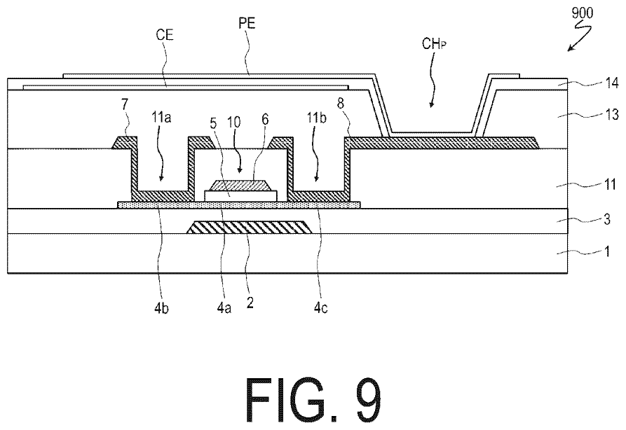

Here, an advantage of the active matrix substrate 100 of the present embodiment will be described by comparing with an active matrix substrate 900 of a comparative example illustrated in FIG. 9.

The active matrix substrate 900 of the comparative example is different from the active matrix substrate 100 of the embodiment in that the active matrix substrate 900 does not include the second interlayer insulating layer 12. In the active matrix substrate 900 of the comparative example, the source electrode 7 and the drain electrode 8 are connected to the source contact region 4b and the drain contact region 4c of the oxide semiconductor layer 4 in the first source opening 11a and the first drain opening 11b, respectively, formed in the first interlayer insulating layer 11. That is, the first source opening 11a and the first drain opening 11b in the first interlayer insulating layer 11 function as a source contact hole and a drain contact hole, respectively.

In general, as the thickness of the insulating layer in which the contact hole is formed becomes large, a hole diameter also becomes large. Thus, in the active matrix substrate 900 of the comparative example, when the thickness of the first interlayer insulating layer 11 is made sufficiently large in order to ensure sufficient insulating properties between a gate metal layer (which is a generic term for an electrode and a wiring line, which are made of the gate conductive film) and a source metal layer (which is a generic term for an electrode and a wiring line, which are made of the source conductive film), the hole diameters of the source contact hole (first source opening 11a) and the drain contact hole (first drain opening 11b) become large.

On the other hand, in the active matrix substrate 100 of the present embodiment, the first interlayer insulating layer 11 and the second interlayer insulating layer 12 are provided between the gate metal layer and the source metal layer, and the second source opening 12a smaller than the first source opening 11a of the first interlayer insulating layer 11 and located inside the first source opening 11a and the second drain opening 12b smaller than the first drain opening 11b of the first interlayer insulating layer 11 and located inside the first drain opening 11b are formed in the second interlayer insulating layer 12. The second source opening 12a and the second drain opening 12b of the second interlayer insulating layer 12 function as a source contact hole and a drain contact hole, respectively. Thus, even when the total of the thicknesses of the first interlayer insulating layer 11 and the second interlayer insulating layer 12 is made sufficiently large in order to sufficiently ensure the insulating properties between the gate metal layer and the source metal layer, the thickness of the second interlayer insulating layer 12 itself in which the second source opening 12a and the second drain opening 12b functioning as the contact holes are formed can be made small to some extent, so that the hole diameters of the source contact hole (second source opening 12a) and the drain contact hole (second drain opening 12b) can be made small. Since the second source opening 12a is located in the first source opening 11a, the photoresist layer formed on the second interlayer insulating layer 12 in the photolithography process for forming the second source opening 12a is thicker in the vicinity of a sidewall of the first source opening 11a. Thus, a shift amount during dry etching becomes further smaller in the vicinity of the sidewall of the first source opening 11a, so that the hole diameter of the source contact hole can also be made smaller. Similarly, since the second drain opening 12b is located in the first drain opening 11b, the thickness of the photoresist layer is thicker in the vicinity of a sidewall of the first drain opening 11b. Thus, a shift amount during dry etching becomes further smaller in the vicinity of the sidewall of the first drain opening 11b, so that the hole diameter of the drain contact hole can also be made smaller. Further, since the hole diameter of the source contact hole can be made small, the width of the source bus line SL can also be made small. As described above, in the active matrix substrate 100 according to the present embodiment, the size of the pixel TFT 10 can be reduced and the wiring lines can be miniaturized, so that the aperture ratio can be improved. Thus, even when the pixel size is made small for an increase in the definition of the display devices, the aperture ratio can be improved or maintained.

As the thickness of the second interlayer insulating layer 12 is smaller, a shift amount (spread in the lateral direction) during dry etching for forming the second source opening 12a and the second drain opening 12b can be made smaller, so that the source contact hole and the drain contact hole can be further miniaturized. In addition, as the thickness of the second interlayer insulating layer 12 is smaller, the thickness of a photoresist layer formed on the second interlayer insulating layer 12 in the photolithography process can be made smaller, so that a higher resolution can be achieved during exposure, so that the source contact hole and the drain contact hole can also be further miniaturized. Thus, from the viewpoint of further miniaturizing the source contact hole and the drain contact hole, a thickness t2 of the second interlayer insulating layer 12 is preferably smaller than a thickness t1 of the first interlayer insulating layer 11. Specifically, the thickness t2 of the second interlayer insulating layer 12 is preferably 200 nm or less, and more preferably 150 nm or less.

A size ratio between the first source opening 11a and the second source opening 12a in a plan view is not particularly limited, but an equivalent circle diameter of the second source opening 12a is, for example, 25% or less of an equivalent circle diameter of the first source opening 11a. Similarly, a size ratio between the first drain opening 11b and the second drain opening 12b in a plan view is not particularly limited, but an equivalent circle diameter of the second drain opening 12b is, for example, 25% or less of an equivalent circle diameter of the first drain opening 11b.

When the second interlayer insulating layer 12 is a silicon nitride layer or has a layered structure including a silicon oxide layer and a silicon nitride layer formed on the silicon oxide layer, a tapered shape of the sidewalls of the second source opening 12a and the second drain opening 12b can be easily formed.

### Second Embodiment

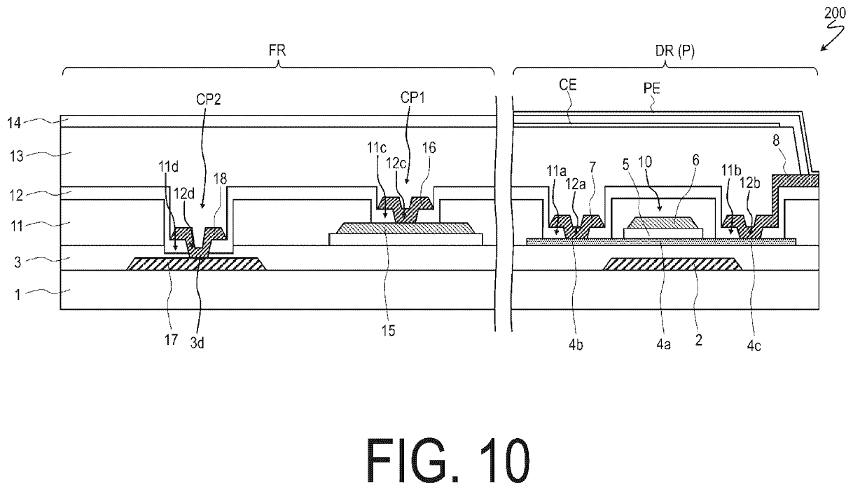

An active matrix substrate 200 in the embodiment will be described with reference to FIG. 10. FIG. 10 is a cross-sectional view schematically illustrating the active matrix substrate 200. In the following, differences between the active matrix substrate 200 and the active matrix substrate 100 of the first embodiment will be mainly described.

A structure of the display region DR (of the pixel region P) is illustrated on the right side in FIG. 10, and a structure of the peripheral region FR is illustrated on the left side in FIG. 10. Since the structure of the display region DR of the active matrix substrate 200 is substantially the same as the structure of the display region DR of the active matrix substrate 100 of the first embodiment, description thereof will be omitted.

As illustrated in FIG. 10, the peripheral region FR of the active matrix substrate 200 includes a first connection portion CP1 and a second connection portion CP2.

The first connection portion CP1 electrically connects a first wiring line 15 made of the same conductive film (i.e., a gate conductive film) as the gate electrodes 6 to a second wiring line 16 made of the same conductive film (i.e., a source conductive film) as the source electrode 7 and the drain electrode 8.

In the peripheral region FR, the first interlayer insulating layer 11 includes a first gate opening 11c formed so as to expose at least a part of the first wiring line 15. The second interlayer insulating layer 12 includes a second gate opening 12c formed so as to be smaller than the first gate opening 11c and to be located inside the first gate opening 11c, in a plan view. The second wiring line 16 is connected to the first wiring line 15 in the second gate opening 12c.

The second connection portion CP2 electrically connects a third wiring line 17 made of the same conductive film (i.e., a conductive film for the light blocking layer) as the light blocking layer 2 to a fourth wiring line 18 made of the same conductive film (i.e., a source conductive film) as the source electrode 7 and the drain electrode 8.

In the peripheral region FR, the first interlayer insulating layer 11 includes a first bottom opening 11d formed so as to expose at least a part of the third wiring line 17. In addition, the lower insulating layer 3 includes a second bottom opening 3d formed so as to be smaller than the first bottom opening 11d and to be located inside the first bottom opening 11d, in a plan view. Further, the second interlayer insulating layer 12 includes a third bottom opening 12d formed so as to be smaller than the first bottom opening 11d and to be located inside the first bottom opening 11d, in a plan view. The third bottom opening 12d is continuous with the second bottom opening 3d. The fourth wiring line 18 is connected to the third wiring line 17 in the second bottom opening 3d and the third bottom opening 12d.

In the active matrix substrate 200 of the present embodiment, in the first connection portion CP1 of the peripheral region FR, as described above, the second gate opening 12c of the second interlayer insulating layer 12 functions as the contact hole, and thus the contact hole can be miniaturized for the same reason as the source contact hole and the drain contact hole in the pixel region P.

In addition, in the second connection portion CP2 of the peripheral region FR, as described above, the second bottom opening 3d of the lower insulating layer 3 and the third bottom opening 12d of the second interlayer insulating layer 12 function as the contact holes, and thus the contact hole can also be miniaturized in the second connection portion CP2. In the case of electrically connecting the lower metal layer (which is a general term for an electrode and a wiring line made of the conductive film for the light blocking layer) to the source metal layer, the etching depth is increased by the amount of the lower insulating layer 3 as compared with the case of electrically connecting the gate metal layer to the source metal layer, so that the hole diameter of the contact hole is also likely to become large. In addition, it is necessary to form the opening in the lower insulating layer 3 while maintaining the selectivity so that the oxide semiconductor layer 4 is not over-etched.

As in the present embodiment, by causing the second bottom opening 3d and the third bottom opening 12d, which are formed to be smaller than the first bottom opening 11d so as to be located inside the first bottom opening 11d of the first interlayer insulating layer 11, to function as the contact holes, the contact holes can be suitably miniaturized also in the second connection portion CP2.

### Other Configuration Example

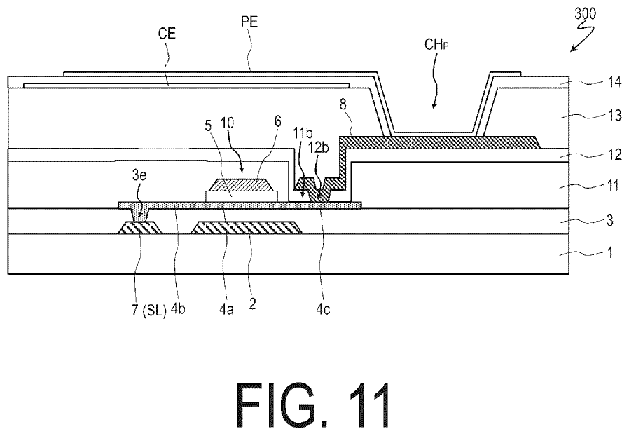

In the first and second embodiments, the configuration has been exemplified in which the second source opening 12a located inside the first source opening 11a is used as the source contact hole, and the second drain opening 12b located inside the first drain opening 11b is used as the drain contact hole, so that both the source contact hole and the drain contact hole can be miniaturized. However, embodiments of the disclosure are not limited to such a configuration. In the embodiment of the disclosure, the configuration in which the opening of the second interlayer insulating layer 12 is formed so as to be located inside the opening of the first interlayer insulating layer 11 may be applied to only one of the source contact hole and the drain contact hole, and only one of the source contact hole and the drain contact hole can be miniaturized. An example of such a configuration is illustrated in FIG. 11.

In the active matrix substrates 100 and 200 of the first and second embodiments, respectively, the source bus line SL and the source electrode 7 are provided on the second interlayer insulating layer 12. On the other hand, in the active matrix substrate 300 illustrated in FIG. 11, the source bus line SL and the source electrode 7 are provided below the lower insulating layer 3. That is, the source bus line SL and the source electrode 7 are covered by the lower insulating layer 3. The source bus line SL and the source electrode 7 can be made of the same conductive film (the conductive film for the light blocking layer) as the light blocking layer 2. The source contact region 4b and the source electrode 7 of the oxide semiconductor layer 4 are connected to each other in an opening 3e formed in the lower insulating layer 3. That is, the opening 3e of the lower insulating layer 3 functions as a source contact hole.

Also in the active matrix substrate 300 illustrated in FIG. 11, since the second drain opening 12b of the second interlayer insulating layer 12 functions as a drain contact hole, the drain contact hole can be miniaturized. Although not illustrated here, it is needless to say that a configuration for miniaturizing only the source contact hole may be adopted.

### Oxide Semiconductor

An oxide semiconductor included in the oxide semiconductor layer 4 may be an amorphous oxide semiconductor, or may be a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

The oxide semiconductor layer 4 may have a layered structure including two or more layers. The oxide semiconductor layer 4 having a layered structure may include an amorphous oxide semiconductor layer and a crystalline oxide semiconductor layer, and may include a plurality of crystalline oxide semiconductor layers having different crystal structures. In addition, the oxide semiconductor layer 4 having a layered structure may include a plurality of amorphous oxide semiconductor layers. In a case where the oxide semiconductor layer 4 has a dual-layer structure including an upper layer and a lower layer, an energy gap of the oxide semiconductor included in the lower layer is preferably greater than an energy gap of the oxide semiconductor included in the upper layer. However, when the difference in energy gap between these layers is relatively small, the energy gap of the oxide semiconductor in the upper layer may be greater than the energy gap of the oxide semiconductor in the lower layer.

Materials, structures, and film formation methods of an amorphous oxide semiconductor and the above-described crystalline oxide semiconductors, a configuration of an oxide semiconductor layer having a layered structure, and the like are described in, for example, JP 2014-007399 A. The entire contents of the disclosure of JP 2014-007399 A are incorporated herein by reference.

The oxide semiconductor layer 4 may include, for example, at least one metal element among In, Ga, and Zn. In the embodiments of the disclosure, the oxide semiconductor layer 4 includes, for example, an In—Ga—Zn—O based semiconductor (indium gallium zinc oxide, for example). Here, the In—Ga—Zn—O based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. Such an oxide semiconductor layer 11 can be formed of an oxide semiconductor film including the In—Ga—Zn—O based semiconductor.

The In—Ga—Zn—O based semiconductor may be an amorphous semiconductor or may be a crystalline semiconductor. A crystalline In—Ga—Zn—O based semiconductor in which a c-axis is oriented substantially perpendicular to a layer surface is preferable as the crystalline In—Ga—Zn—O based semiconductor.

Note that a crystal structure of the crystalline In—Ga—Zn—O based semiconductor is disclosed in, for example, JP 2014-007399 A as described above, JP 2012-134475 A, and JP 2014-209727 A. The entire contents of the disclosure of JP 2012-134475 A and JP 2014-209727 A are incorporated herein by reference. A TFT including an In—Ga—Zn—O based semiconductor layer has a high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In—Ga—Zn—O based semiconductor, the oxide semiconductor layer 4 may include another oxide semiconductor. There may be included, for example, an In—Sn—Zn—O based semiconductor (for example, In₂O₃—SnO₂—Zno; InSnZnO). The In—Sn—Zn—O based semiconductor is a ternary oxide of In (indium), Sn (tin), and Zn (zinc). Alternatively, the oxide semiconductor layer 4 may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, and an In—Ga—Zn—Sn—O based semiconductor.

### Liquid Crystal Display Device

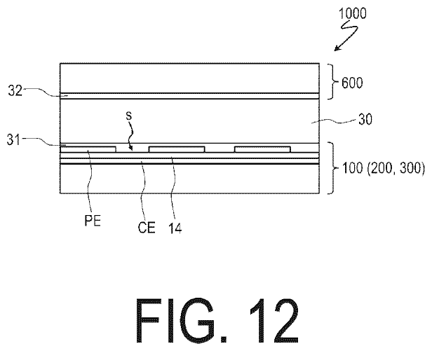

The active matrix substrates 100, 200, and 300 according to the embodiments of the disclosure can be suitably used in a liquid crystal display device. FIG. 12 illustrates an example of the liquid crystal display device.

A liquid crystal display device 1000 illustrated in FIG. 12 includes the active matrix substrate 100 (or the active matrix substrate 200 or 300), a counter substrate 600 provided so as to face the active matrix substrate 100, and a liquid crystal layer 30 provided between the active matrix substrate 100 and the counter substrate 600.

The active matrix substrate 100 includes the TFT 10 (not illustrated here) disposed in each pixel region P, the pixel electrode PE electrically connected to the TFT 10, the dielectric layer 14 provided so as to cover the pixel electrode PE, and the common electrode CE provided on the dielectric layer 14 and facing the pixel electrode PE. At least one slit s is formed in the common electrode CE for each pixel region P.

Each of alignment films 31 and 32 is provided on the outermost surface on the liquid crystal layer 30 side of a respective one of the active matrix substrate 100 and the counter substrate 600. The counter substrate 600 typically includes a color filter layer and a black matrix (both not illustrated).

A thickness (cell gap) of the liquid crystal layer 30 can be defined by a columnar spacer (not illustrated here) provided on the liquid crystal layer 30 side of the counter substrate 600.

Note that although the liquid crystal display device 1000 of the FFS mode which is a type of transverse electrical field mode is exemplified here, the active matrix substrate according to the embodiments of the disclosure may be used for liquid crystal display devices of other display modes. In a liquid crystal display device of a vertical electrical field mode such as a twisted nematic (TN) mode or a vertical alignment (VA) mode, a common electrode is provided at a counter substrate side.

In addition, the display device according to the embodiment of the disclosure is not limited to the liquid crystal display device and may be another display device, for example, an organic EL display device. The organic EL display device includes an organic EL layer provided on a pixel electrode.

### INDUSTRIAL APPLICABILITY

According to embodiments of the disclosure, the aperture ratio of the active matrix substrate including the oxide semiconductor TFT having the top gate structure and the display device can be improved. The active matrix substrate according to the embodiment of the disclosure is suitably used for various display devices such as a liquid crystal display device, an organic EL display device, or the like.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. Active matrix substrate comprising:
a display region including a plurality of pixel regions and a peripheral region located around the display region;
a substrate;
a pixel TFT supported by the substrate and provided corresponding to each of the plurality of pixel regions; and
a pixel electrode disposed in each of the plurality of pixel regions and electrically connected to the pixel TFT, the pixel TFT including an oxide semiconductor layer including a channel region, and a source contact region and a drain contact region located on both sides of the channel region, respectively, a gate insulating layer provided on the channel region of the oxide semiconductor layer, a gate electrode provided on the gate insulating layer and facing the channel region via the gate insulating layer, and a source electrode electrically connected to the source contact region of the oxide semiconductor layer,
wherein the active matrix substrate further includes a first interlayer insulating layer covering the gate electrode and the oxide semiconductor layer and a second interlayer insulating layer provided on the first interlayer insulating layer,
the source electrode is provided on the second interlayer insulating layer,
the first interlayer insulating layer includes a first source opening formed so as to expose at least a part of the source contact region,
the second interlayer insulating layer includes a second source opening formed so as to be smaller than the first source opening and to be located inside the first source opening in a plan view, and
the source electrode is connected to the source contact region in the second source opening.

2. The active matrix substrate according to claim 1,
wherein the pixel TFT includes a drain electrode electrically connected to the drain contact region of the oxide semiconductor layer,
the drain electrode is provided on the second interlayer insulating layer,
the first interlayer insulating layer includes a first drain opening formed so as to expose at least a part of the drain contact region,
the second interlayer insulating layer includes a second drain opening formed so as to be smaller than the first drain opening and to be located inside the first drain opening in a plan view, and
the drain electrode is connected to the drain contact region in the second drain opening.

3. The active matrix substrate according to claim 1,
wherein the peripheral region includes a first connection portion electrically connecting a first wiring line made of the same conductive film as the gate electrode to a second wiring line made of the same conductive film as the source electrode,
the first interlayer insulating layer includes a first gate opening formed so as to expose at least a part of the first wiring line,
the second interlayer insulating layer includes a second gate opening formed so as to be smaller than the first gate opening and to be located inside the first gate opening in a plan view, and
the second wiring line is connected to the first wiring line in the second gate opening.

4. The active matrix substrate according to claim 1, further comprising:
a light blocking layer provided on the substrate and having electrical conductivity; and
a lower insulating layer covering the light blocking layer,
wherein the oxide semiconductor layer is provided on the lower insulating layer,
the peripheral region includes a second connection portion electrically connecting a third wiring line made of the same conductive film as the light blocking layer to a fourth wiring line made of the same conductive film as the source electrode,
the first interlayer insulating layer includes a first bottom opening formed so as to expose at least a part of the third wiring line,
the lower insulating layer includes a second bottom opening formed so as to be smaller than the first bottom opening and to be located inside the first bottom opening in a plan view,
the second interlayer insulating layer includes a third bottom opening formed so as to be smaller than the first bottom opening and to be located inside the first bottom opening in a plan view, the third bottom opening being continuous with the second bottom opening, and
the fourth wiring line is connected to the third wiring line in the second bottom opening and the third bottom opening.

5. Active matrix substrate comprising:
a display region including a plurality of pixel regions, and a peripheral region located around the display region;
a substrate;
a pixel TFT supported by the substrate and provided corresponding to each of the plurality of pixel regions; and
a pixel electrode disposed in each of the plurality of pixel regions and electrically connected to the pixel TFT, the pixel TFT including an oxide semiconductor layer including a channel region, and a source contact region and a drain contact region located on both sides of the channel region, respectively, a gate insulating layer provided on the channel region of the oxide semiconductor layer, a gate electrode provided on the gate insulating layer and facing the channel region via the gate insulating layer, and a drain electrode electrically connected to the drain contact region of the oxide semiconductor layer,
wherein the active matrix substrate further includes a first interlayer insulating layer covering the gate electrode and the oxide semiconductor layer and a second interlayer insulating layer provided on the first interlayer insulating layer,
the drain electrode is provided on the second interlayer insulating layer,
the first interlayer insulating layer includes a first drain opening formed so as to expose at least a part of the drain contact region,
the second interlayer insulating layer includes a second drain opening formed so as to be smaller than the first drain opening and to be located inside the first drain opening in a plan view, and
the drain electrode is connected to the drain contact region in the second drain opening.

6. The active matrix substrate according to claim 5,
wherein the peripheral region includes a first connection portion electrically connecting a first wiring line made of the same conductive film as the gate electrode to a second wiring line made of the same conductive film as the drain electrode,
the first interlayer insulating layer includes a first gate opening formed so as to expose at least a part of the first wiring line,
the second interlayer insulating layer includes a second gate opening formed so as to be smaller than the first gate opening and to be located inside the first gate opening in a plan view, and
the second wiring line is connected to the first wiring line in the second gate opening.

7. The active matrix substrate according to claim 5, further comprising:
a light blocking layer provided on the substrate and having electrical conductivity; and
a lower insulating layer covering the light blocking layer,
wherein the oxide semiconductor layer is provided on the lower insulating layer,
the peripheral region includes a second connection portion electrically connecting a third wiring line made of the same conductive film as the light blocking layer to a fourth wiring line made of the same conductive film as the drain electrode,
the first interlayer insulating layer includes a first bottom opening formed so as to expose at least a part of the third wiring line,
the lower insulating layer includes a second bottom opening formed so as to be smaller than the first bottom opening and to be located inside the first bottom opening in a plan view,
the second interlayer insulating layer includes a third bottom opening formed so as to be smaller than the first bottom opening and to be located inside the first bottom opening in a plan view, the third bottom opening being continuous with the second bottom opening, and
the fourth wiring line is connected to the third wiring line in the second bottom opening and the third bottom opening.

8. The active matrix substrate according to claim 1,
wherein a thickness of the second interlayer insulating layer is smaller than a thickness of the first interlayer insulating layer.

9. The active matrix substrate according to claim 1,
wherein a thickness of the second interlayer insulating layer is 200 nm or less.

10. The active matrix substrate according to claim 1,
wherein the second interlayer insulating layer is a silicon nitride layer or has a layered structure including a silicon oxide layer and a silicon nitride layer formed on the silicon oxide.

11. The active matrix substrate according to claim 1,
wherein the oxide semiconductor layer includes an In—Ga—Zn—O based semiconductor.

12. The active matrix substrate according to claim 11,
wherein the In—Ga—Zn—O based semiconductor includes a crystalline portion.

13. A display device comprising:
the active matrix substrate according to claim 1.

14. The display device according to claim 13,
wherein the display device is a liquid crystal display device including a counter substrate disposed facing the active matrix substrate and a liquid crystal layer provided between the active matrix substrate and the counter substrate.

15. A method of manufacturing the active matrix substrate according to claim 1, comprising:
(A) forming the oxide semiconductor layer, the gate insulating layer, and the gate electrode;
(B) forming the first interlayer insulating layer so as to cover the gate electrode and the oxide semiconductor layer;
(C) forming the first source opening in the first interlayer insulating layer by a photolithography process and etching;
(D) forming the second interlayer insulating layer on the first interlayer insulating layer and in the first source opening;
(E) forming the second source opening in the second interlayer insulating layer by a photolithography process and etching; and
(F) forming the source electrode on the second interlayer insulating layer and in the second source opening.

16. A method of manufacturing the active matrix substrate according to claim 5, comprising:
(A) forming the oxide semiconductor layer, the gate insulating layer, and the gate electrode;
(B) forming the first interlayer insulating layer so as to cover the gate electrode and the oxide semiconductor layer;
(C) forming the first drain opening in the first interlayer insulating layer by a photolithography process and etching;
(D) forming the second interlayer insulating layer on the first interlayer insulating layer and in the first drain opening;
(E) forming the second drain opening in the second interlayer insulating layer by a photolithography process and etching; and
(F) forming the drain electrode on the second interlayer insulating layer and in the second drain opening.
